(19) United States
(12) Patent Application Publication
(10) Pub. No.: US 2014/0011333 A1
(43) Pub. Date: Jan. 9, 2014

(54) POLYCRYSTALLINE SILICON EFUSE AND RESISTOR FABRICATION IN A METAL REPLACEMENT GATE PROCESS

(71) Applicants: Benjamin P. McKee, Richardson, TX (US); Yongqiang Jiang, Plano, TX (US); Douglas T. Grider, McKinney, TX (US)

(72) Inventors: Benjamin P. McKee, Richardson, TX (US); Yongqiang Jiang, Plano, TX (US); Douglas T. Grider, McKinney, TX (US)

(73) Assignee: Texas Instruments Incorporated, Dallas, TX (US)

(21) Appl. No.: 13/544,354

(22) Filed: Jul. 9, 2012

(51) Int. Cl. H01L 21/8238; H01L 21/28; H01L 21/02

(52) U.S. Cl. 438/210; 438/382; 438/586; 257/E21.19; 257/E21.004; 257/E21.641

(57) ABSTRACT

A method of fabricating an integrated circuit is disclosed (FIGS. 1-2). The method comprises providing a substrate (200) having an isolation region (202) and etching a trench in the isolation region. A first conductive layer (214) is formed within the trench. A first transistor having a first conductivity type (n-channel) is formed at a face of the substrate. The first transistor has a gate (216) formed of the first conductive layer. A second transistor having a second conductivity type (p-channel) is formed at the face of the substrate. The second transistor has a gate (224) formed of the first conductive layer. The method further comprises replacing the first conductive layer of the first transistor with a first metal gate (132) and replacing the first conductive layer of the second transistor with a second metal gate (134).

### BACKGROUND OF THE INVENTION

Embodiments of the present invention relate to fabrication of a polycrystalline silicon efuse in a complementary metal oxide semiconductor (CMOS) metal replacement gate process.

Shrinking semiconductor integrated circuit feature sizes have placed increasing challenges on semiconductor integrated circuit processing. In particular, a balance between high packing density and yield requires a finely tuned manufacturing process. Recent process advances include various stress memorization techniques (SMT) in both p-channel and n-channel complementary metal oxide semiconductor (CMOS) circuits, metal gate replacement, and composite gate dielectric materials such as silicon oxynitride (SiON). Such advanced processes, however, may present compatibility issues with other integrated circuit features. Efuses, for example, are used in many integrated circuits for row and column redundancy selection, integrated circuit identification, programmable logic functions, and other functions. With metal gate replacement, however, polycrystalline silicon is no longer readily available for efuses. Therefore, some integrated circuit manufacturers have converted to copper efuses formed in the back end of line (BEOL) process after first interlevel oxide (ILD1) deposition. Copper efuses, however, have a relatively low resistance and require high current to program or blow them. Moreover, they present some programming reliability issues regarding incomplete programming and copper leakage contamination. Therefore, there is a need for a polycrystalline silicon efuse/resistor that is reliable, compatible with metal gate replacement processes, and programmable at a relatively low voltage and a current density of less than 8 A/μm² without a high cost associated with excessive process complexity.

### BRIEF SUMMARY OF THE INVENTION

In a preferred embodiment of the present invention, a method of fabricating an integrated circuit is disclosed. The method comprises providing a substrate having an isolation region. A trench is etched in the isolation region, and a first conductive layer is formed within the trench. A first transistor having a first conductivity type is formed at a face of the substrate. The first transistor has a gate formed of the first conductive layer. A second transistor having a second conductivity type is formed at the face of the substrate. The second transistor has a gate formed of the first conductive layer. The method further comprises replacing the first conductive layer of the first transistor with a first metal gate and replacing the first conductive layer of the second transistor with a second metal gate.

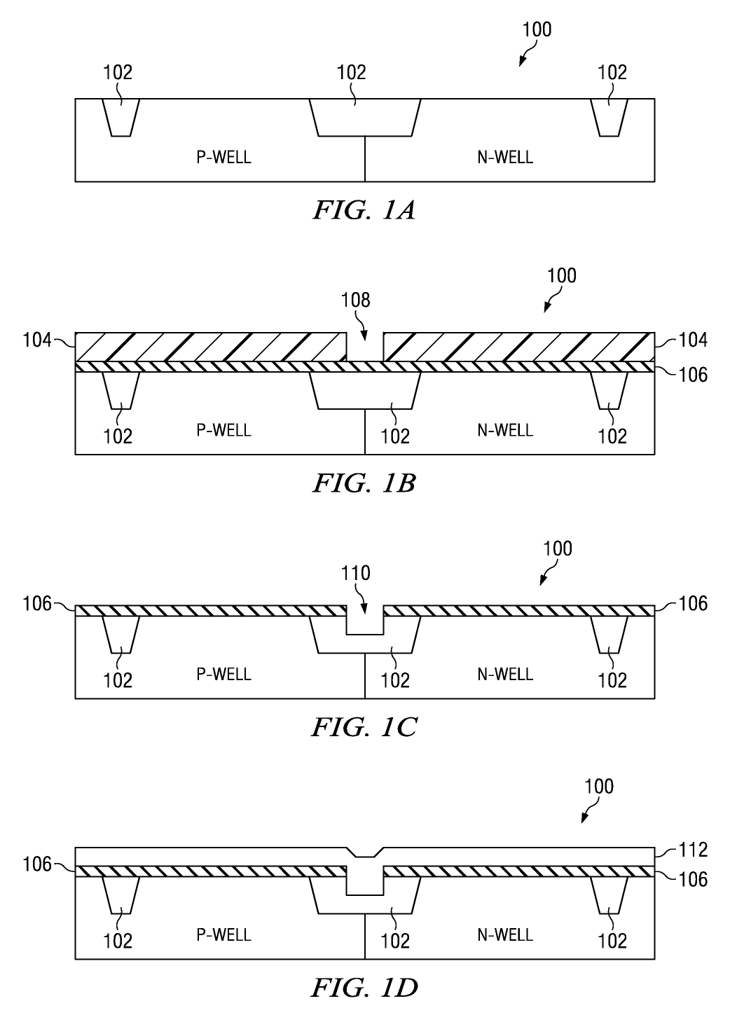

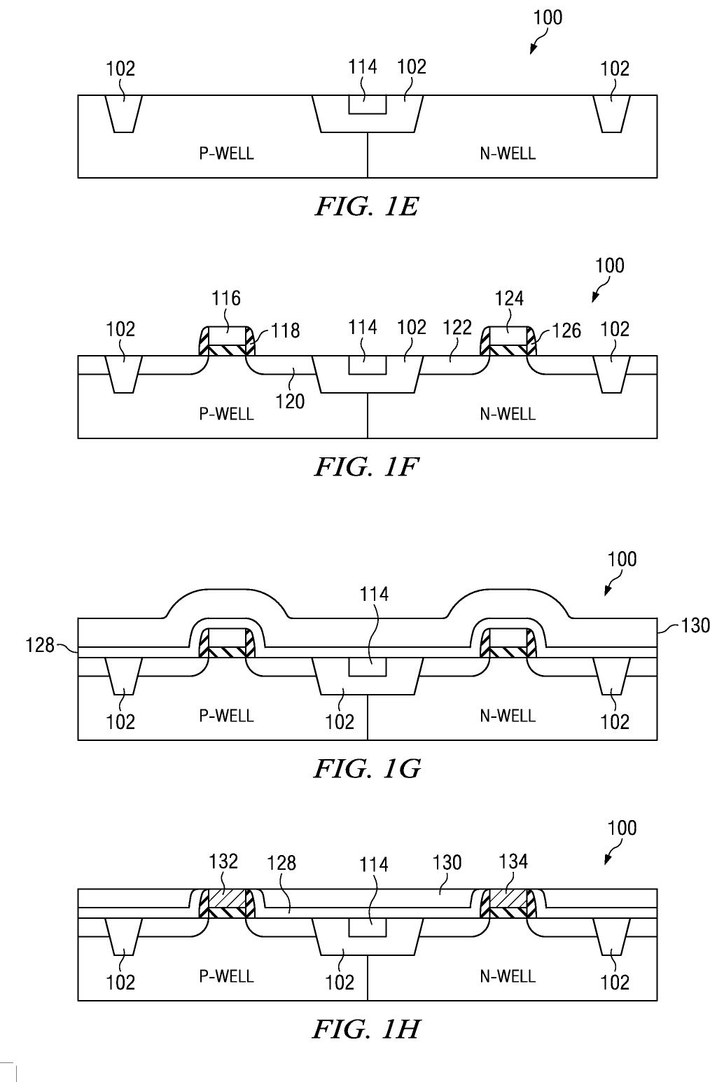

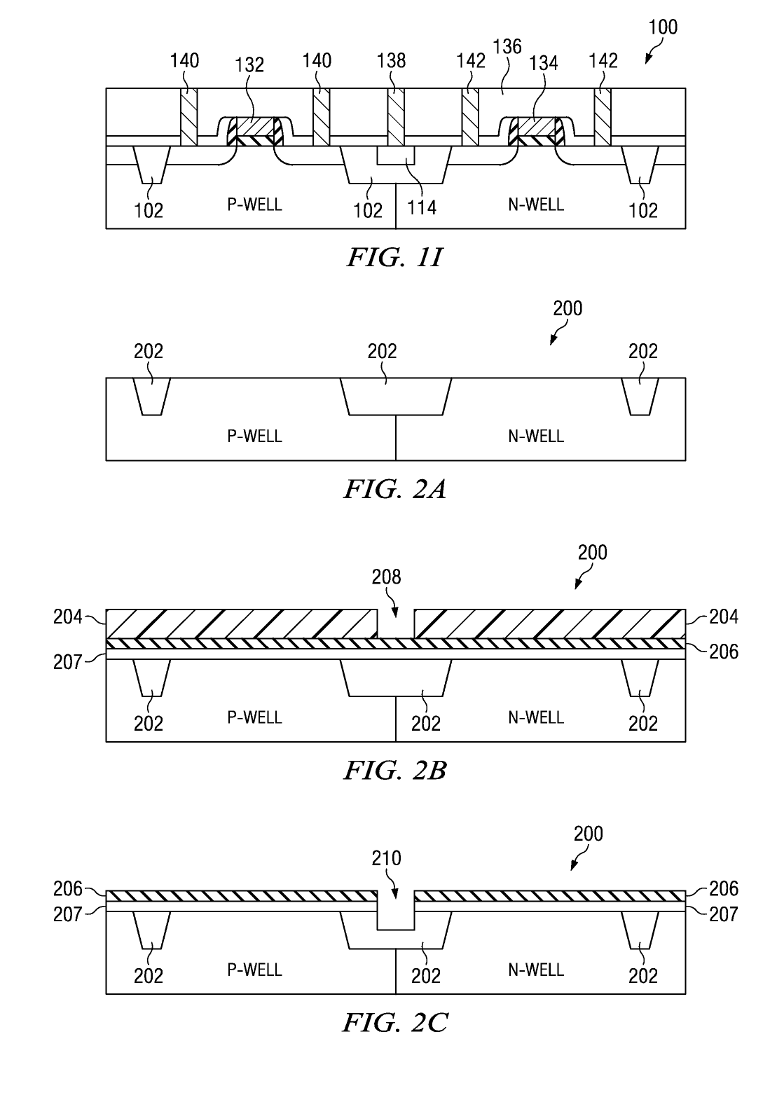

FIGS. 1A through 1I are diagrams of a simplified process flow according to a first embodiment of the present invention;

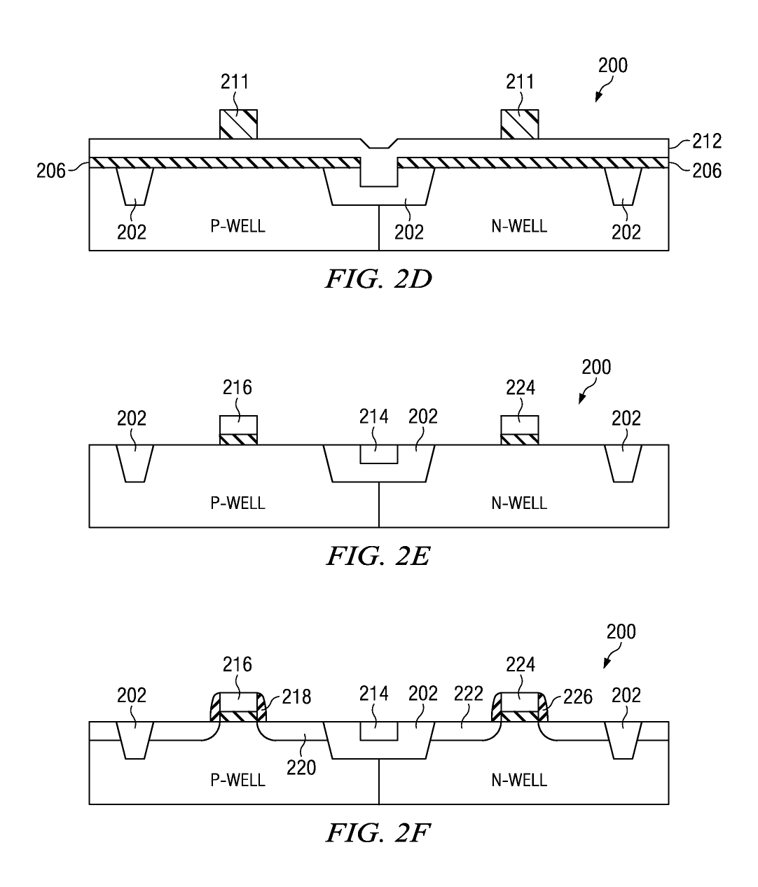

FIGS. 2A through 2F and 1G through 1I are diagrams of a simplified process flow according to a second embodiment of the present invention; and

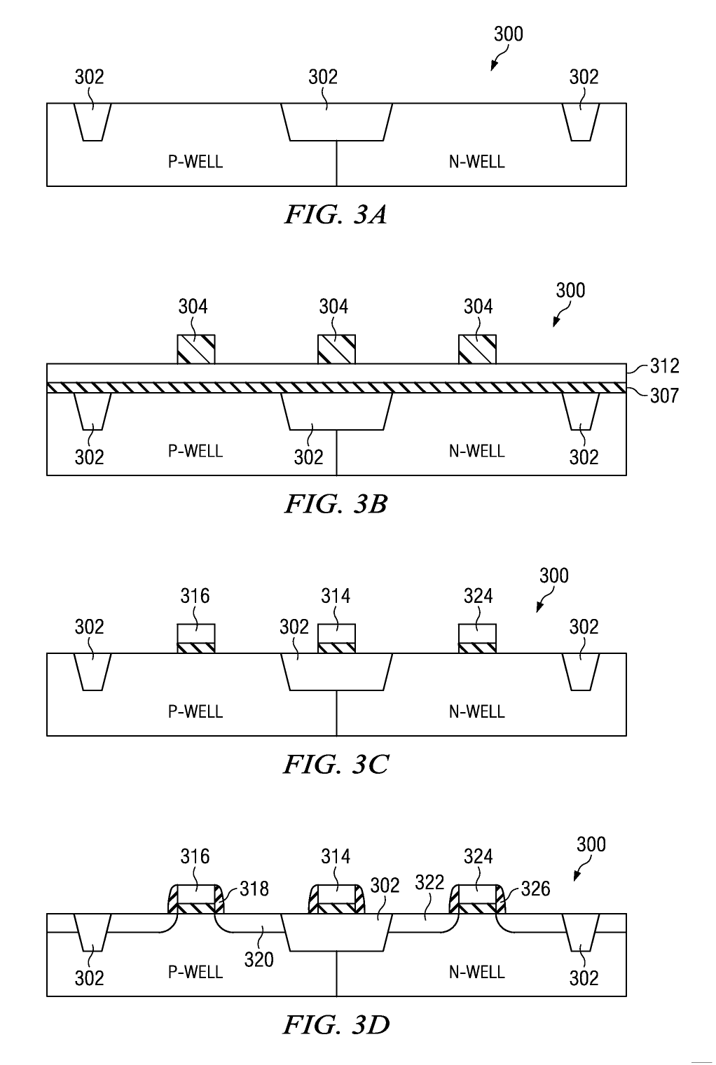

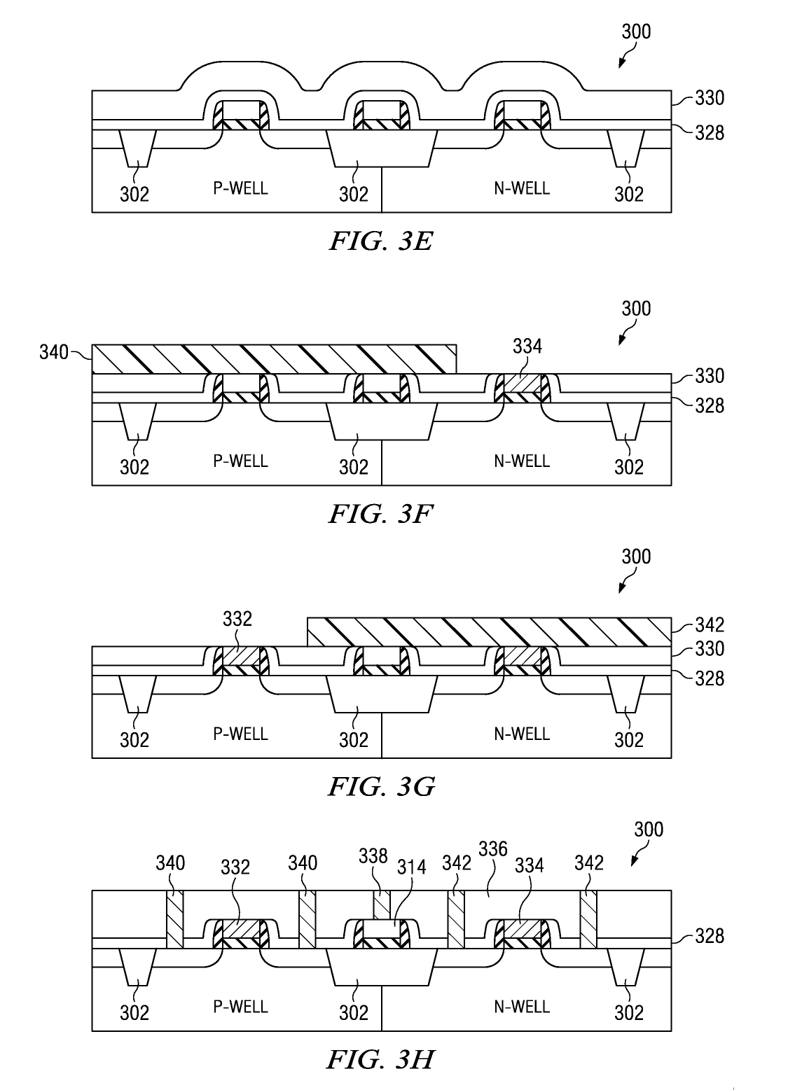

FIGS. 3A through 3H are diagrams of a simplified process flow according to a third embodiment of the present invention.

### DETAILED DESCRIPTION OF THE INVENTION

The preferred embodiments of the present invention provide significant advantages in efuse/resistor fabrication for a metal replacement gate process over efuse/resistor technology of the prior art.

Referring now to FIGS. 1A through 1I there are diagrams of a simplified process flow according to a first embodiment of the present invention. FIG. 1A illustrates a semiconductor substrate 100 having shallow trench isolation (STI) regions 102 as is well known in the art. The left half of the substrate is designated p-well as a bulk terminal for re-channel metal oxide semiconductor (NMOS) transistors. The right half of the substrate is designated n-well as a bulk terminal for p-channel metal oxide semiconductor (PMOS) transistors. Here, and in the following discussion, drawing figures illustrate a simplified fabrication process flow rather than a particular circuit. The drawing figures are not to scale, and the same reference numerals are used to identify similar features.

At FIG. 1B, a hard mask 106 is formed over the substrate 100 of FIG. 1A. The hard mask is generally an inorganic anti-reflective coating (IARC) and may be silicon nitride (SiN), silicon carbide (SiC), or other suitable material that does not react with underlying layers during processing. A photoresist layer 104 is formed over the hard mask 106 layer and opening 108 is patterned in the photoresist layer.

At FIG. 1C, the hard mask 106 and part of the STI 102 are etched according to photoresist pattern 108 to produce a trench 110 in the STI dielectric. Photoresist layer 104 is subsequently removed by a standard ash and clean process.

At FIG. 1D, conductive layer 112 is formed over the substrate 100 and in the trench 110 of FIG. 1C. The conductive layer 112 is preferably polycrystalline silicon and may be n-type, p-type, or undoped.

At FIG. 1E, the surface of substrate 100 is planarized by standard chemical mechanical polishing (CMP) to remove a portion of conductive layer 112 and hard mask layer 106. Alternatively, the portion of conductive layer 112 and hard mask layer 106 may be removed by a standard plasma etch process. Thus, a portion 114 of conductive layer 112 remains in the STI trench and will to serve as the efuse material or resistor as will be explained in detail.

At FIG. 1F, an NMOS transistor is formed at a face of substrate 100 within the p-well region. The NMOS transistor includes a sacrificial gate layer 116, sidewall spacers 118, and N+ source/drain regions 120. A PMOS transistor is also formed at the face of substrate 100 within the n-well region. The PMOS transistor includes the sacrificial gate layer 124, sidewall spacers 126, and P+ source/drain regions 122. A metal silicide layer such as titanium silicide, tantalum silicide, or platinum silicide may optionally be formed over source/drain regions 120, 122 and efuse/resistor layer 114.

At FIG. 1G, preplanarization layers 128 and 130 are preferably formed over substrate 100 of FIG. 1F by chemical vapor deposition (CVD), low pressure CVD (LPCVD), or plasma enhanced CVD (PECVD), for example. Layer 128 may be, for example, SiN, SiON, or SiC. Layer 130 is preferably deposited silicon dioxide.

At FIG. 1H, the substrate 100 is preferably planarized by CMP. Sacrificial gate layers 116 and 124 (FIG. 1F) are preferably removed by a wet etch or other suitable method that preserves the underlying gate dielectric. Here and in the following discussion it should be understood that the NMOS and PMOS replacement gates may be processed simultaneously or separately to provide different metal replacement gates with different work functions. The NMOS transistor gate is formed by a first metal layer 132. Similarly, the PMOS transistor gate is formed by a second metal layer 134. As previously mentioned, layers 132 and 134 may be formed from the same or different metal layers and may comprise, for example, hafnium, zirconium, tungsten, titanium, tantalum, titanium nitride, titanium aluminum nitride, aluminum, platinum, or other suitable metal or metal alloy having a suitable work function.

Finally, at FIG. 1I, a first interlevel dielectric 136 is deposited over substrate 100. Vias 140 are formed for NMOS source/drain regions, vias 142 are formed for PMOS source/drain regions, and via 138 is formed for efuse/resistor region 114.

Referring now to FIGS. 2A through 2F there are diagrams of a simplified process flow according to a second embodiment of the present invention. FIG. 2A illustrates a semiconductor substrate 200 having shallow trench isolation (STI) regions 202 as is well known in the art. The left half of the substrate is designated p-well as a bulk terminal for NMOS transistors. The right half of the substrate is designated n-well as a bulk terminal for PMOS transistors.

At FIG. 2B, a dielectric layer 207 is formed over substrate 200. The dielectric layer may be thermally grown silicon dioxide or a deposited high-k dielectric such as SiON or SiN. Here, high-k refers to a dielectric generally having a relative permittivity greater than 10. A hard mask 206 is formed over the dielectric layer 207 of FIG. 2A. The hard mask is generally an IARC layer as previously described. A photoresist layer 204 is formed over the hard mask 206 layer and opening 208 is patterned in the photoresist layer.

At FIG. 2C, the hard mask 206, dielectric layer 207, and part of the STI 202 are etched according to photoresist pattern 208 to produce a trench 210 in the STI dielectric. Photoresist layer 204 is subsequently removed by a standard ash and clean process.

At FIG. 2D, conductive layer 212 is formed over the dielectric layer 206 and in the trench 210 of FIG. 2C. The conductive layer 212 is preferably polycrystalline silicon and may be n-type, p-type, or undoped. A photoresist layer is subsequently deposited and patterned to produce mask regions 211.

At FIG. 2E, substrate 200 is etched according to the mask pattern 211 to produce gate stack regions 216 and 224 and to produce efuse/resistor region 214 within trench 210. Photoresist layer 211 is subsequently removed by a standard ash and clean process.

At FIG. 2F, an NMOS transistor is formed at a face of substrate 200 within the p-well region. The NMOS transistor includes a conductive layer 216, sidewall spacers 218, and N+ source/drain regions 220. A PMOS transistor is also formed at the face of substrate 200 within the n-well region. The PMOS transistor includes the conductive layer 224, sidewall spacers 226, and P+ source/drain regions 222. A metal silicide layer such as titanium silicide, tantalum silicide, or platinum silicide may optionally be formed over source/drain regions 220, 222 and efuse/resistor layer 214.

After processing at FIG. 2F, substrate 200 is processed as previously described at FIGS. 1G through if The previously described embodiments of the present invention are highly advantageous over methods of the prior art for several reasons. First, no additional masks are required for either embodiment. A mask to form the efuse/resistor layer is added and a mask to form a copper or other efuse is removed from the process. Second, the efuse layer of the present invention is much more flexible than copper efuses, since it may be formed of doped or undoped polycrystalline silicon and may be include a metal silicide layer, be fully silicided (FUSI) or be unsilicided. Third, the resistance and eutectic temperature may be adjusted to provide reliable programming at process compatible levels of voltage and current Finally, the efuse/resistor layer may be formed partially or entirely over STI to avoid damage or shorting to nearby structures during programming.

Referring now to FIGS. 3A through 3H there are diagrams of a simplified process flow according to a third embodiment of the present invention. FIG. 3A illustrates a semiconductor substrate 300 having shallow trench isolation (STI) regions 302 as is well known in the art. The left half of the substrate is designated p-well as a bulk terminal for n-channel metal oxide semiconductor (NMOS) transistors. The right half of the substrate is designated n-well as a bulk terminal for p-channel metal oxide semiconductor (PMOS) transistors.

At FIG. 3B, a dielectric layer 307 is formed over substrate 300. The dielectric layer may be thermally grown silicon dioxide or a deposited high-k dielectric such as SiON or SiN. Here, high-k refers to a dielectric generally having a relative permittivity greater than 10. A conductive layer 312 is formed over the dielectric layer 307. The conductive layer 112 is preferably polycrystalline silicon and may be n-type, p-type, or undoped. A photoresist layer is formed and patterned over the conductive layer 312 layer to produce mask regions 304.

At FIG. 3C, substrate 300 is etched according to the mask pattern 304 to produce gate stack regions 316 and 324 and to produce efuse/resistor region 314. Photoresist regions 304 are subsequently removed by a standard ash and clean process.

At FIG. 3D, an NMOS transistor is formed at a face of substrate 300 within the p-well region. The NMOS transistor includes a conductive layer 316, sidewall spacers 318, and N+ source/drain regions 320. A PMOS transistor is also formed at the face of substrate 200 within the n-well region. The PMOS transistor includes the conductive layer 324, sidewall spacers 326, and P+ source/drain regions 322. Sidewall spacers are also formed adjacent efuse/resistor region 314. A metal silicide layer such as titanium silicide, tantalum silicide, or platinum silicide may optionally be formed over source/drain regions 320 and 322.

At FIG. 3E, preplanarization layers 328 and 330 are preferably formed over substrate 300 of FIG. 3D by chemical vapor deposition (CVD), low pressure CVD (LPCVD), or plasma enhanced CVD (PECVD), for example. Layer 328 may be, for example, SiN, SiON, or SiC. Layer 330 is preferably deposited silicon dioxide.

At FIG. 3F, the substrate 300 is preferably planarized by CMP. In this embodiment, where NMOS and PMOS gates are separately replaced, a photoresist layer is deposited and patterned to produce mask layer 340. Here and in the following discussion it should be understood that the order of separate gate replacement is optional. Mask layer 340 covers the NMOS transistor and the efuse/resistor layer 314. Conductive gate layer 324 (FIG. 3D) is preferably removed by a wet etch or other suitable method that preserves the underlying gate dielectric. The PMOS transistor gate is then formed by a metal layer that is etched back to produce metal gate 334.

At FIG. 3G, a photoresist layer is deposited and patterned to produce mask layer 342. Mask layer 342 covers the PMOS transistor and the efuse/resistor layer 314. Conductive gate layer 316 (FIG. 3D) is preferably removed by a wet etch or other suitable method that preserves the underlying gate dielectric. The NMOS transistor gate is then formed by a metal layer that is etched back to produce metal gate 332. Here, metal gate layers 332 and 334 may comprise, for example, hafnium, zirconium, tungsten, titanium, tantalum, titanium nitride, titanium aluminum nitride, aluminum, platinum, or other suitable metal or metal alloy having a suitable work function.

Finally, at FIG. 3H, photoresist layer 304 is subsequently removed by a standard ash and clean process. A metal silicide may optionally be formed over region 314 by metal deposition and anneal as is well known in the art. No additional mask is required, since the metal will not react with dielectric layers 328 and 330 or with metal gates 332 and 334. A first interlevel dielectric 336 is deposited over substrate 300. Vias 340 are formed for NMOS source/drain regions, vias 342 are formed for PMOS source/drain regions, and via 338 is formed for efuse/resistor region 314. In addition to the previously mentioned advantages of the present invention, this embodiment advantageously eliminates a mask to form a copper or other efuse from the process. No additional masks are required.

Still further, while numerous examples have thus been provided, one skilled in the art should recognize that various modifications, substitutions, or alterations may be made to the described embodiments while still falling within the inventive scope as defined by the following claims. Other combinations will be readily apparent to one of ordinary skill in the art having access to the instant specification.

1: A method of fabricating an integrated circuit, comprising:
providing a substrate having an isolation region;
etching a trench in the isolation region;
forming a first conductive layer within the trench, wherein the first conductive layer within the trench comprises an efuse;
forming a first transistor having a first conductivity type at a face of the substrate, the first transistor having a gate formed of a sacrificial gate layer;
forming a second transistor having a second conductivity type at the face of the substrate, the second transistor having a gate formed of the sacrificial gate layer;
replacing the sacrificial gate layer of the first transistor with a first metal gate; and
replacing the sacrificial gate layer of the second transistor with a second metal gate.

2: (canceled)

3: A method as in claim 1, comprising:
forming a first source/drain region of the first transistor; and
forming a second source/drain region of the second transistor.

4: A method as in claim 1, wherein the first metal gate comprises a different material than the second metal gate.

5: A method as in claim 1, wherein the first transistor is an n-channel metal oxide semiconductor (NMOS) transistor, and wherein the first metal gate comprises TiAlN.

6: A method as in claim 1, wherein the second transistor is a p-channel metal oxide semiconductor (PMOS) transistor, and wherein the second metal gate comprises TiN.

7-8. (canceled)

9: A method of fabricating an integrated circuit, comprising:
providing a substrate having an isolation region;
etching a trench in the isolation region;
forming a first conductive layer within the trench;
forming a first transistor having a first conductivity type at a face of the substrate, the first transistor having a gate formed of the first conductive layer;
forming a second transistor having a second conductivity type at the face of the substrate, the second transistor having a gate formed of the first conductive layer;
replacing the first conductive layer of the first transistor with a first metal gate; and
replacing the first conductive layer of the second transistor with a second metal gate.

10: (canceled)

11: A method as in claim 9, comprising:
forming a first source/drain region of the first transistor; and
forming a second source/drain region of the second transistor.

12: A method as in claim 9, wherein the first metal gate comprises a different material than the second metal gate.

13: A method as in claim 9, wherein the first transistor is an n-channel metal oxide semiconductor (NMOS) transistor, and wherein the first metal gate comprises TiAlN.

14: A method as in claim 9, wherein the second transistor is a p-channel metal oxide semiconductor (PMOS) transistor, and wherein the second metal gate comprises TiN.

15: A method as in claim 9, wherein the first conductive layer within the trench comprises an efuse.

16: A method as in claim 9, wherein the first conductive layer within the trench comprises a resistor.

17-20. (canceled)
